(19) United States
(12) Patent Application Publication
(10) Pub. No.: US 2017/0260648 A1
(43) Pub. Date: Sep. 14, 2017

(54) METHOD FOR PRODUCING GROUP III NITRIDE CRYSTAL, AND RAMO4-CONTAINING SUBSTRATE

(71) Applicant: Panasonic Intellectual Property Management Co., Ltd., Osaka (JP)

(72) Inventors: YOSHIO OKAYAMA, Osaka (JP); MASAKI NOBUOKA, Nara (JP)

(21) Appl. No.: 15/411,792

(22) Filed: Jan. 20, 2017

(30) Foreign Application Priority Data
Mar. 14, 2016 (JP) 2016-049607

(51) Int. Cl. C30B 19/12; C30B 19/06; C30B 29/40; C30B 19/02

(52) U.S. Cl. CPC C30B 19/12; C30B 19/02; C30B 19/062; C30B 29/403

(57) ABSTRACT

A method for producing a Group III nitride crystal includes: preparing a protective layer on a region except for an epitaxial growth surface of an RAMO₄ substrate containing a single crystal represented by the general formula RAMO₄ (wherein R represents one or a plurality of a trivaient element selected from a group of elements including: Sc, In, Y, and a lanthanoid element, A represents one or a plurality of a trivalent element selected from a group of elements including: Fe(III), Ga, and Al, and M represents one or a plurality of a divalent element selected from a group of elements including: Mg, Mn, Fe(II), Co, Cu, Zn, and Cd); and forming a Group III nitride crystal on the epitaxial growth surface of the RAMO₄ substrate by a flux method.

### TECHNICAL FIELD

The technical field relates to a method fox producing a Group III nitride crystal, and an RAMO₄-containing substrate.

### BACKGROUND

In recent years, a crystal of a Group III nitride, such as GaN, is receiving attention as a material of a light emitting diode and the like. As one of the production methods of the crystal of a Group III nitride, a flux method has been known, in which a Group III element and nitrogen are reacted in a flux of Na or the like, and a crystal is grown on a substrate. The substrate used herein is generally a sapphire substrate or the like (see, for example, Patent Literatures 1 and 2). However, a sapphire substrate has a lattice mismatch ratio of 13.8% to GaN, and when a Group III nitride crystal is grown on a sapphire substrate, there is a problem that crystal defects are liable to occur.

As a substrate for producing a Group III nitride, a substrate formed of a single crystal represented by the general formula RAMO₄ (wherein R represents one or a plurality of a trivalent element selected from the group consisting of Sc, In, Y, and a lanthanoid element, A represents one or a plurality of a trivalent element selected from the group consisting of Fe(III), Ga, and Al, and M represents one or a plurality of a divalent element selected from the group consisting of Mg, Mn, Fe(II), Co, Cu, Zn, and Cd) (which may be hereinafter referred simply to as an “RAMO₄ substrate”), examples of which include ScAlMgO₄, has been proposed as a material having a small lattice mismatch ratio (see, for example, Patent Literature 3).

Patent Literature 1: JP-A-2007-246341

Patent Literature 2: Japanese Patent No. 4,716,711

Patent Literature 3: JP-A-2015-178448

### SUMMARY

Under the circumstances, the application of the RAMO₄ substrate described in the Patent Literature 3 to the flux method may be considered. However, when the RAMO₄ substrate is immersed in a flux, such as Na, the elements constituting the RAMO₄ substrate may be mixed in the flux. When the elements are mixed in the flux, the elements tend to be incorporated into the Group III nitride crystal, and the change of the crystal lattice size and the band structure and the change of the electric characteristics (such as the electroconductivity) tend to occur.

One of the objects of an object herein is to provide a method for producing a Group III nitride crystal with high quality on an RAMO₄ substrate by a flux method.

For achieving the aforementioned and other objects, there is provided, as one aspect, a method for producing a Group III nitride crystal, containing: preparing a protective layer on a region except for an epitaxial growth surface of an RAMO₄ substrate containing a single crystal represented by the general formula RAMO₄ (wherein R represents one or a plurality of a trlvaient element selected from a group of elements including: Sc, In, Y, and a lanthanoid element, A represents one or a plurality of a trlvaient element selected from a group of elements including: Fe(III), Ga, and Al, and M represents one or a plurality of a divalent element selected from a group of elements including: Mg, Mn, Fe(II), Co, Cu, Zn, and Cd) (i.e., a protective layer forming step); and forming a Group III nitride crystal on the epitaxial growth surface of the RAMO₄ substrate by a flux method (i.e., a crystal growing step).

According to the aspect, in the production of a Group III nitride crystal by a flux method, the elements constituting the RAMO₄ substrate may be mixed in the flux, and a Group III nitride crystal with high quality can be produced.

### BRIEF DESCRIPTION OF THE DRAWINGS

FIGS. 1A and 1B are schematic cross sectional views showing a crystal production equipment used in one embodiment.

FIG. 2 is a schematic cross sectional view showing an example of an RAMO₄ substrate used in one embodiment.

FIG. 3 is a schematic cross sectional yiew showing another example of an RAMO₄ substrate used in one embodiment.

### DESCRIPTION OF EMBODIMENTS

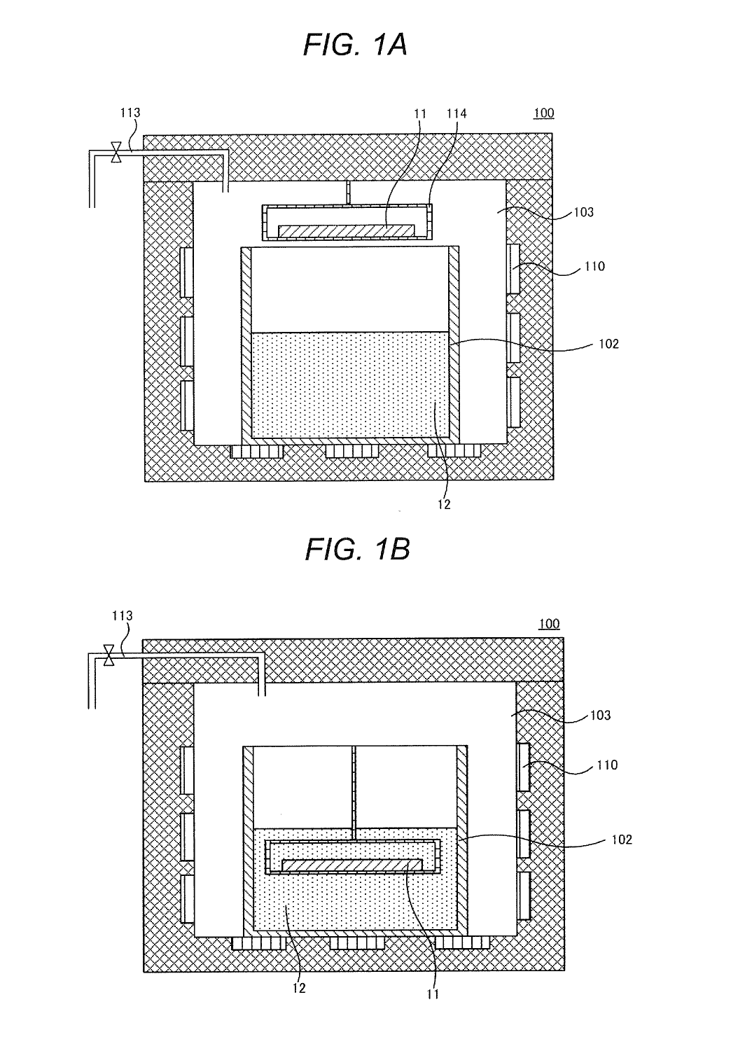

FIGS. 1A and 1B are schematic cross sectional views showing an example of a reaction equipment (crystal production equipment) 100 for performing a flux method in the embodiment. As shown in FIG. 1B, in the method for producing a Group III nitride of the embodiment, nitrogen gas is introduced to a reaction chamber 103 in the state where an RAMO₄ substrate 11 is immersed in a mixed liquid 12 containing a Group III element and a flux. The Group III element and nitrogen are reacted with each other in the mixed liquid 12 to grow a crystal of a Group III nitride on the surface of the RAMO₄ substrate 11, and thereby the target Group III nitride crystal is obtained.

As the substrate for producing a crystal used in the method of this type, a sapphire substrate has been generally used. However, a sapphire substrate has a large lattice mismatch ratio to GaN and the like, and the resulting Group III nitride crystal, such as GaN, tends to have lattice defects or the like. Under the circumstances described above, the application of an RAMO₄ substrate (such as an ScAlMgO₄ substrate) having a small lattice mismatch ratio to GaN and the like has been considered. However, it has been found that in the application of the RAMO₄ substrate to the flux method, the elements derived from the RAMO₄ substrate tend to be incorporated into the resulting Group III nitride crystal, and the change of the crystal lattice size and the band structure and the change of the electric characteristics (such as the electroconductivity) tend to occur. The mechanism thereof will be described with reference, for example, to the case where a crystal of GaN is produced by immersing a substrate formed of a single crystal of ScAlMgO₄ in an Na flux.

In the Na flux method, an ScAlMgO₄ substrate is immersed in a mixed liquid containing a molten Na at a high temperature (which may be hereinafter referred to as an “Na flux”) and Ga, and the crystal growth of GaN is performed on the ScAlMgO₄ substrate. At this time, the ScAlMgO₄ substrate is dissolved in the Na flux, and Sc, Al, and Mg are eluted in the Na flux. The trivalent elements (i.e., Sc and Al) eluted in the Na flux tend to be bonded to N instead of Ga and incorporated into the interior of the GaN crystal. As a result, the crystal lattice size and the band structure of the GaN crystal are changed to deteriorate the quality of the resulting GaN crystal. The divalent element (i.e., Mg) also tends to be incorporated into the interior of the GaN crystal instead of Ga in some cases. In this case, Mg functions as an acceptor due to the difference in valence. As a result, the electric characteristics (such as the electroconductivity) are changed to prevent the desired capability from being obtained.

In view of this problem, as well as other concerns, the embodiment uses an RAMO₄-containing substrate having a protective layer that covers a region except for an epitaxial growth surface of an RAMO₄ substrate, and produces a Group III nitride crystal by a flux method. According to the method of the embodiment, even though the RAMO₄-containing substrate is immersed in an Na flux or the like, the elements derived from the RAMO₄ substrate are prevented from being eluted. Accordingly, the elements derived from the RAMO₄ substrate are prevented from being incorporated into the resulting Group III nitride crystal, and a Group III nitride crystal with high quality can be obtained.

In the production method of the embodiment, a step of preparing an RAMO₄-containing substrate having a protective layer that protects a region except for an epitaxial growth surface of an RAMO₄ substrate (i.e., a substrate preparing step), and a step of forming a Group III nitride crystal on a region that is not covered with the protective layer of the RAMO₄-containing substrate by a flux method (i.e., a crystal forming step) are performed. The method for producing a Group III nitride crystal according to the embodiment will be described below with reference to the case as one example where the RAMO₄ substrate is a substrate formed of a single crystal of ScAlMgO₄ (which may be hereinafter referred to as an “ScAlMgO₄ substrate”), and a GaN crystal is produced as the Group III nitride crystal.

### Preparation of RAMO₄-Containing Substrate

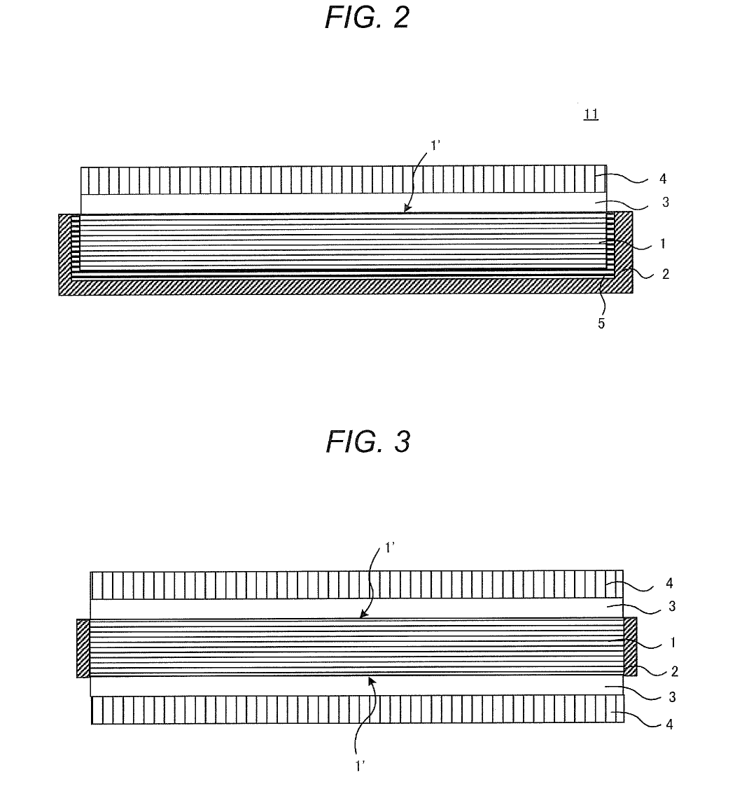

The substrate for producing a crystal contains at least an ScAlMgO₄ substrate and a protective layer that covers a region except for an epitaxial growth surface of the ScAlMgO₄ substrate. In the description herein, the “epitaxial growth surface 1′ of the ScAlMgO₄ substrate 1” means the surface of the ScAlMgO₄ substrate, on which a crystal of GaN is to be epitaxially grown. In the RAMO₄-containing substrate 11 of the embodiment, the ScAlMgO₄ substrate 1 may have the epitaxial growth surface 1′ on only one surface thereof as shown in FIG. 2. In this case, the region except for the epitaxial growth surface 1′ of the ScAlMgO₄ substrate 1 means the surface of the ScAlMgO₄ substrate 1 opposite to the epitaxial growth surface 1′ and the side surfaces thereof. That is, the protective layer 2 is a layer that covers the entire or a part of the surface of the ScAlMgO₄ substrate 1 opposite to the epitaxial growth surface 1′ and the side surfaces thereof. The protective layer 2 may not cover the entire or a part of the side surfaces, and preferably covers the entire of the side surfaces for providing effectively the effect of the embodiment. In the RAMO₄-containing substrate 11 of the embodiment, the ScAlMgO₄ substrate 1 may have the epitaxial growth surfaces 1′ on both surfaces thereof as shown in FIG. 3. In this case, the region except for the epitaxial growth surface 1′ of the ScAlMgO₄ substrate 1 means the side surfaces of the ScAlMgO₄ substrate 1. That is, the protective layer 2 is a layer that covers the entire or a part of the side surfaces of the ScAlMgO₄ substrate 1.

The protective layer 2 may be formed directly on the ScAlMgO₄ substrate 1, and a buffer layer 5 on the protective layer side is preferably formed between the ScAlMgO₄ substrate 1 and the protective layer 2 as shown in FIGS. 2 and 3.

In the RAMO₄-containing substrate 11 of the embodiment, other layers may be formed on the epitaxial growth surface 1′ of the ScAlMgO₄ substrate 1, and a low temperature buffer layer 3 and a seed crystal layer 4 are preferably formed on the epitaxial growth surface 1′ of the ScAlMgO₄ substrate 1 as shown in FIGS. 2 and 3 from the standpoint of the production of a GaN crystal that is uniform and has less defects.

The layers contained in the ScAlMgO₄-containing substrate 11 will be described below.

The ScAlMgO₄ substrate 1 is a substrate formed of a single crystal of ScAlMgO₄, and preferably has a thickness of approximately from 100 to 1,000 μm, and more preferably from 300 to 600 μm. The thickness of the ScAlMgO₄ substrate 1 in this range may facilitate the enhancement of the strength of the ScAlMgO₄-contalning substrate 11, preventing breakage or the like in the production of a GaN crystal. The shape of the ScAlMgO₄ substrate 1 is not particularly limited, and is preferably in the form of a wafer having a diameter of approximately from 50 to 150 mm taking the industrial practicality into consideration.

The epitaxial growth surface of the ScAlMgO₄ substrate 1 preferably does not have irregularities having a height of 500 nm or more on the surface thereof. When the epitaxial growth surface has irregularities having a height of 500 nm or more, a problem may occur in the epitaxial growth of GaN on the ScAlMgO₄-containing substrate 1.

In the case where the ScAlMgO₄ substrate 1 has the epitaxial growth surface 1′ on only one surface thereof as shown in FIG. 2, the surface of the ScAlMgO₄ substrate 1 that is opposite to the epitaxial growth surface 1′ (which may be hereinafter referred to as a “back surface”) preferably has substantially uniform irregularities having a height of 500 nm or more formed homogeneously thereon. When the irregularities having a uniform height of 500 nm or more are formed on the back surface of the ScAlMgO₄ substrate 1, the protective layer 2 and the buffer layer 5 on the protective layer side can be suppressed from being released off. The “substantially uniform irregularities having a height of 500 nm or more formed homogeneously” mean that the irregularities having a substantially uniform height are formed in such a manner that the area of the region having continuously a height of the irregularity of less than 500 nm is 1 mm² or less. When the irregularities are formed locally, there may be a possibility that the protective layer 2 and the buffer layer 5 on the protective layer side are released off from the portion having no irregularity. Furthermore, there may be a possibility that light that is used for an exposure treatment for forming a pattern of a GaN crystal or a semiconductor layer, a metal layer or the like formed thereon is reflected by the flat portion of the back surface and may cause an influence on the exposure. The height of the irregularities herein is a value that is measured by a laser reflection length measuring device.

The ScAlMgO₄ substrate can be produced in the following manner. As starting materials, Sc₂O₃, Al₂O₃, and MgO each having a purity of 4N (99.99%) or more are mixed in the prescribed molar ratio. The starting material is placed in a crucible formed of iridium. The crucible having the starting material placed therein is then placed in a high-frequency induction heating type or resistance heating type Czochralski furnace as a growing furnace, and the interior of the furnace is vacuumed. Thereafter, nitrogen or argon is introduced therein, and at the time when the interior of the furnace is at atmospheric pressure, the crucible is heated. The starting material is melted by gradually heating the material over approximately 10 hours to the melting point of ScAlMgO₄. An ScAlMgO₄ single crystal having been cut into the (0001) axis direction is used as a seed crystal, and the seed crystal is descended to the vicinity of the molten liquid in the crucible. Thereafter, while rotating the seed crystal, the seed crystal is gradually descended to make the tip end of the seed crystal in contact with the molten liquid, and then the seed crystal is raised at a raising speed of 0.5 mm/h in the (0001) axis direction while gradually decreasing the temperature, to grow a crystal. According to the procedure, a single crystal ingot of ScAlMgO₄ is obtained.

The ScAlMgO₄ single crystal will foe described. The ScAlMgO₄ single crystal has a structure containing an ScO₂ layer like the (111) plane of the rock salt structure and an AlMgO₂ layer like the (0001) plane of the hexagonal structure, which are laminated alternately. The two layers like the (0001) plane of the hexagonal structure are of a planar structure as compared to the wurtzite structure, and the bond between the upper and lower layers is longer than the bond in the plane by approximately 0.03 nm, and has a weak bond strength. Accordingly, the ScAlMgO₄ single crystal can be cleaved at the (0001) plane. By utilizing the characteristics, a bulk material thereof can be divided through cleavage to provide an ScAlMgO₄ substrate having a desired thickness.

However, the ScAlMgO₄ single crystal can be easily cleaved, but when the cleaving force in the cleavage direction on cleavage is fluctuated, the cleavage does not occur in the same atomic layer, and it is difficult to provide a flat epitaxial growth surface in this case. Accordingly, in the production of the ScAlMgO₄ substrate, the cleaved surface on the side of the epitaxial growth surface is preferably processed by polishing to avoid an irregularity having a height of 500 nm or more. Examples of the processing method include a method of forming an irregularity having a height of 500 nm or more in the region to be the epitaxial growth surface on the ScAlMgO₄ substrate, and then polishing the irregularity having a height of 500 nm or more to remove the irregularity having a height of 500 nm or more.

More specifically, the surface to be the epitaxial growth surface of the ScAlMgO₄ substrate is ground under the following condition with a whetstone having diamond abrasive grains of #300 or more and #2000 or less attached thereto, and thereby an irregularity having a height of 500 nm or more can be formed. The rotation number of the whetstone may be 500 min⁻¹ or more and 50,000 min⁻¹ or less, the rotation number of the ScAlMgO₄ substrate may be 10 min⁻¹ or more and 300 min⁻¹ or less, the processing speed say be 0.01 μm/sec or more and 1 μm/sec or less, and the processing elimination amount may be 1 μm or more and 300 μm or less. Subsequently, the substrate is polished under the following condition with a polishing pad formed of a slurry mainly containing colloidal silica and a nonwoven fabric, and thereby an irregularity having a height of 500 nm or more can be removed. The rotation number of the polishing pad may be 10 min⁻¹ or more and 1,000 min⁻¹ or less, the slurry supplying amount may be 0.02 mL/min or more and 2 mL/min or less, and the pressure applied may be 1,000 Pa or mere and 20,000 Pa or less. Furthermore, the pressure applied may be decreased with the progress of the processing to 10,000 Pa or more and 20,000 Pa or less, 5,000 Pa or more and 10,000 Pa or more, and 1,000 Pa or more and 5,000 Pa or less, in this order, and thereby the epitaxial growth surface that does not have an irregularity having a height of 500 nm or more, and particularly does not have an irregularity having a height of 50 nm or more, can be formed precisely. In the aforementioned processing condition, the slurry supplying amount depends on the size of the ScAlMgO₄ substrate. The aforementioned slurry supplying amount is a value for polishing a substrate having a 10 mm square size, and for a diameter of 50 mm, for example, the slurry supplying amount may be 1 mL/min or more and 100 mL/min or less.

Examples of the method for homogenously forming the irregularity having a uniform height of 500 nm or more on the back surface include a method of processing by grinding with a diamopnd fixed whetstone. The abrasive grains of the fixed whetstone are preferably diamond abrasive grains of #300 or more and #2000 or less, and more preferably diamond abrasive grains of #600. More specifically, the substrate may be processed by grinding with a whetstone having dimaond abrasive grains of #300 or more and #2000 or less fixed thereto, under the condition of a rotation number of the whetstone of 500 min⁻¹ or more and 50,000 min⁻¹ or less, a rotation number of the ScAlMgO₄ substrate of 10 min⁻¹ or more and 300 min⁻¹ or less, a processing speed of 0.01 μm/sec or more and 1 μm/sec or less, and a processing elimination amount of 1 μm or more and 300 μm or less, and thereby the irregularity can be formed. At this time, by using a diamond whetstone of #600, the differences in height among the plural peaks in the irregularity can foe further decreased. The processing condition in this case is preferably a rotation number of the whetstone of 1,800 min⁻¹, a rotation number of the ScAlMgO₄ substrate of 100 min⁻¹, a processing speed of 0.3 μm/sec, and a processing elimination amount of 20 μm.

The protective layer 2 is a layer that has a function of protecting the ScAlMgO₄ substrate in the production of a GaN crystal by a flux method. The protective layer 2 may be formed of a material that is not dissolved in a flux (such as an Na flux), and may be a layer formed, for example, of SiO₂, AlN, carbon, SiN, Al₂O₃, Ta, GaN, or the like. Among these, AlN, SiN, Al₂O₃, and GaN are preferred. When the protective layer 2 is a layer formed of these materials, the component constituting the protective layer is prevented from being eluted in the Na flux, and lattice defects or the like are prevented from being formed in the resulting GaN crystal.

The thickness of the protective layer 2 is preferably 0.05 μm or more and 5 μm or less, and more preferably 0.1 μm or more and 1 μm or less. When the thickness of the protective layer 2 is 0.05 μm or more, the component of the ScAlMgO₄ substrate can be sufficiently prevented from being eluted on immersing the ScAlMgO₄-containing substrate in the flux. When the thickness of the protective layer 2 is 5 μm or less, cracks are prevented from being formed in the protective layer 2, and thus the component of the ScAlMgO₄ substrate can be similarly prevented from being eluted.

The formation method of the protective layer 2 is not particularly limited, and any method can be used that can form a uniform layer on the ScAlMgO₄ substrate 1 or the buffer layer 5 on the protective layer side described later. Examples of the formation method of the protective layer 2 include a PVD (physical vapor deposition) method, such as a sputtering method, a vacuum vapor deposition method, and an ion plating method, and a CVD (chemical vapor deposition) method, such as a plasma CVD method and an MOCVD method. In the formation of the protective layer 2 by these methods, the epitaxial growth surface 1′ of the ScAlMgO₄ substrate 1 is preferably protected with a mask or the like depending on necessity. According to the procedure, the protective layer 2 can be formed on the region except for the epitaxial growth surface 1′ of the ScAlMgO₄ substrate 1.

The buffer layer 5 on the protective layer side is a layer that is formed between the protective layer 2 and the ScAlMgO₄ substrate, and is for enhancing the adhesion between the protective layer 2 and the ScAlMgO₄ substrate 1. The buffer layer 5 on the protective layer side may be formed of the similar material as the protective layer 2. However, the thermal expansion coefficient of the buffer layer 5 on the protective layer side is preferably a value that is between the thermal expansion coefficient of the ScAlMgO₄ substrate 1 and the thermal expansion coefficient of the protective layer 2. In the case where the thermal expansion coefficient of the protective layer 2 and the thermal expansion coefficient of the ScAlMgO₄ substrate 1 are largely different from each other, a stress may be formed at the interface between the protective layer 2 and the ScAlMgO₄ substrate 1 due to the heat in the formation of the GaN crystal, and thereby the ScAlMgO₄ substrate 1 and the protective layer 2 may be separated from each other in some cases. In the case where the buffer layer 5 on the protective layer side is formed between the ScAlMgO₄ substrate 1 and the protective layer 2, on the other hand, the separation is hard to occur at the interface between the ScAlMgO₄ substrate 1 and the buffer layer 5 on the protective layer side and the interface between the protective layer 2 and the buffer layer 5 on the protective layer side, and thereby the protective layer 2 may be prevented from being released off.

The thermal expansion coefficient of the buffer layer 5 on the protective layer side can be controlled by the formation conditions including the material constituting the buffer layer 5 on the protective layer side, the temperature, and the like. Either the thermal expansion coefficient of the protective layer 2 or the thermal expansion coefficient of the ScAlMgO₄ substrate 1 may be larger than the other. For example, the thermal expansion coefficient may be increased in the order of the protective layer 2, the buffer layer 5 on the protective layer side, and the ScAlMgO₄ substrate 1, and the thermal expansion coefficient may be increased in the order of the ScAlMgO₄ substrate 1, the buffer layer 5 on the protective layer side, and the protective layer 2, The buffer layer 5 on the protective layer side may contain two or more layers. In this case, the layer closer to the ScAlMgO₄ substrate 1 preferably has a thermal expansion coefficient that is closer to that of the ScAlMgO₄ substrate 1.

The thickness of the buffer layer 5 on the protective layer side is preferably 0.01 μm or more and 5 μm or less, and more preferably 0.01 μm or more and 0.5 μm or less. In this case, however, the thickness of the buffer layer 5 on the protective layer side is preferably smaller than the thickness of the protective layer 2. When the thickness of the buffer layer 5 on the protective layer side Is too large, the buffer layer 5 on the protective layer side tends to be cracked, and the protective layer 2 tends to be released off.

The production method of the buffer layer 5 on the protective layer side is not particularly limited, and the production method thereof may be a known formation method, and may be same as the formation method of the protective layer 2.

The low temperature buffer layer 3 formed on the ScAlMgO₄ substrate 1 on the side of the epitaxial growth surface 1′ is a layer for buffering the difference in lattice contstant between the ScAlMgO₄ substrate and GaN formed on the ScAlMgO₄-containing substrate 11. The low temperatuer buffer layer 3 is preferrably an amorphous or poiycrystalline layer of GaN grown at a relatively low temperature of 400° C. or more and 700° C. or less. When the ScAlMgO₄-containing substrate 11 has the low temperature buffer layer 3, lattice defects or the like are prevented from being formed in the resulting GaN crystal.

The low temperature buffer layer 3 stay be a layer formed of GaN. The thickness of the low temperature buffer layer 3 is preferably 10 nm or more and 50 nm or less, and more preferably 20 nm or more and 40 nm or less. When the thickness of the low temperature buffer layer is 10 nm or more, the effect of buffering the difference in lattice constant can be exhibited, and lattice defects or the like are prevented from being formed in the resulting GaN crystal. When the thickness of the low temperature buffer layer is too large, favorable epitaxial growth may not be performed due to the loss of the information of the crystal lattice.

The buffer layer 3 can be formedby a vapor phase epitaxial method, and may be, for example, a layer formed by an MOCVD method.

The seed crystal layer 4 is a layer that functions as a seed for GaN crystal growth in the production of a crystal of GaN. When the ScAlMgO₄-containing substrate 11 has the seed crystal layer 4, the crystal of GaN can be grown uniformly to facilitate the formation of high quality GaN. The seed crystal layer 4 may be a layer formed of GaN.

The thickness of the seed crystal layer 4 is preferably from 0.5 μm or more and 20 μm or less, and more preferably 1 μm or more and 5 μm or less. When the thickness of the seed crystal layer 4 is 0.5 μm or more, the seed crystal layer 4 formed on the amorphous or poiycrystaiiine low temperature buffer layer 3 may be a favorable single crystal to prevent the formation of lattice defects and the like in the resulting crystal of GaN. The seed crystal layer 4 can be formed by a vapor phase epitaxial method, and can be formed, for example, by an MOCVD method. The temperature in the formation of the seed crystal layer 4 is preferably 1,000° C. or more and 1,300° C. or less, and more preferably 1,100° C. or more and 1,200° C. or less. The seed crystal layer 4 with good crystal quality can be formed within this temperature range.

The surface of the ScAlMgO₄-containing substrate 11, on which a GaN crystal is to be grown, i.e., the surface of the seed crystal layer 4 in this embodiment, may be subjected to a cleaning treatment before producing the GaN crystal. The cleaning treatment can remove impurities and the like on the surface, and thereby a GaN crystal with higher quality can be obtained. Examples of the gas for cleaning include hydrogen (H₂) gas, nitrogen (N₂) gas, ammonia (NH₃), gas, a rare gas (such as He, Ne, Ar, Kr, Xe, and Rn), and mixed gases thereof. The cleaning treatment may be performed by making contact with the gas at a temperature of 900° C. or more and 1,100° C. or less for 1 minute or more, and preferably 2 minutes or more and 10 minutes or less.

### Production of GaN Crystal

Subsequently, a GaN crystal is formed on the seed crystal layer 4 of the RAMO₄-containing substrate by a flux method. The GaN crystal can be formed, for example, by using the equipment shown in FIGS. 1A and 1B in the following manner.

As shown in FIGS. 1A and 1B, the reaction equipment 100 has a reaction chamber 103 formed with a stainless steel, a thermal insulating material, and the like, and a crucible 102 is disposed in the reaction chamber 103. The crucible may be formed of boron nitride (BN), alumina (Al₂O₃), or the like. A heater 110 is disposed around the reaction chamber 103, and the heater 110 is designed to be able to control the temperature inside the reaction chamber 103, particularly inside the crucible 102.

The reaction equipment 100 also has thereinside a substrate retention mechanism 114 for retaining liftably an ScAlMgO₄-containing substrate 11. A nitrogen supplying line 113 for supplying nitrogen gas is connected to the reaction chamber 103, and the nitrogen supplying line 113 is connected to a raw material gas tank (which is not shown in the figure) or the like.

In the production of the GaN crystal, an Na flux and Ga as a Group III element are placed in the crucible 102 in the reaction chamber 103 of the reaction equipment 100. At this time, a trace additive may be added thereto depending on necessity. If the operation is performed in the air, there is a possibility that Na is oxidized. Therefore, the operation is preferably performed in a state, in which an inert gas, such as Ar and nitrogen gas, is filled. Subsequently, the reaction chamber 103 is sealed, the temperature of the crucible is controlled to 800° C. or more and 1,000° C. or less, and more preferably 800° C. or more and 950° C. or less, and further nitrogen gas is charged in the reaction chamber 103. At this time, the gas pressure in the reaction chamber may be 1×10⁶ Pa or more and 1×10⁷ Pa or less, and more preferably 3×10⁶ Pa or more and 5×10⁶ Pa or less. The increase of the gas pressure in the reaction chamber 103 may facilitate the sufficient dissolution of nitrogen in the Na flux, and the temperature and the pressure thus controlled as above may grow the GaN crystal at a high rate. Thereafter, the operation of retention, mixing by agitation, or the like is performed until the Na flux, Ga, and the trace additive are uniformly mixed. The operation of retention or mixing by agitation is preferably performed for a period of time of from 1 to 50 hours, and more preferably from 10 to 25 hours. The operation of retention or mixing by agitation performed for the period of time may mix the Na flux, Ga, and the trace additive uniformly. At this time, if the ScAlMgO₄-containing substrate 11 is in contact with the mixed liquid 12 of the Na flux and Ga that has a temperature lower than the prescribed temperature or is not mixed uniformly, etching of the seed crystal layer 4, deposition of the GaN crystal with poor quality, and the like may occur. Accordingly, the ScAlMgO₄-containing substrate 11 is preferably retained at the upper part of the reaction chamber 103 with the substrate retention mechanism 114.

Thereafter, as shown in FIG. 1B, the ScAlMgO₄-containing substrate 11 is immersed in the mixed liquid 12. The mixed liquid 12 may be agitated. The agitation of the mixed liquid 12 may be performed by a physical movement of the crucible 102, such as vibration and rotation, and the mixed liquid 12 may be agitated with an agitation bar or an agitation blade. The mixed liquid 12 may also be agitated through thermal convection by forming a heat gradient in the mixed liquid 12. The agitation may retain the concentrations of Ga and N uniformly in the mixed liquid 12, thereby growing the crystal stably. Thus, a GaN crystal can be epitaxially grown on the seed crystal layer 4 of the ScAlMgO₄-containing substrate 11. The crystal is grown in this state for a certain period of time, and thereby a GaN crystal having a thickness of approximately from 100 μm to 5 mm can be obtained.

The electroconductivity and the band gap of the resulting GaN crystal can be controlled by adding a trace additive along with Na and Ga. Examples of the trace additive include compounds containing boron (B), thallium (Tl), and calcium (Ga), silicon (Si), sulfur (S), selenium (Se), tellurium (Te), carbon (C), oxygen (O), aluminum (Al), indium (In), alumina (Al₂O₃), indium nitride (InN), silicon nitride (Si₃N₄), silicon oxide (SiO₂), indium oxide (In₂O₃), zinc (Zn), magnesium (Mg), zinc oxide (ZnO), magnesium oxide (MgO), and germanium (Ge). The trace additive may be added solely, or two or more kinds thereof may be added.

### Other Embodiments

While the embodiment where the RAMO₄-containing substrate contains the ScAlMgO₄-containing substrate has been described, the embodiment is not limited thereto. It suffices that the substrate contained in the RAMO₄-containing substrate is a substrate that is constituted by a substantially sole crystal material represented by the general formula RAMO₄. In the general formula, R represents one or a plurality of a trivalent element selected from Sc, In, Y, and a lanthanoid element (atomic number; 67 to 71), A represents one or a plurality of a trivaient element selected from Fe(III), Ga, and Al, and M represents one or a plurality of a divalent element selected from Mg, Mn, Fe(II), Co, Cu, Zn, and Cd. The substantially sole crystal material means a crystalline solid, in which the material contains 90% by atom or more of the structure represented by RAMO₄, and in terms of an arbitrary crystal axis, the direction of the crystal axis is not changed in any part on the epitaxial growth surface. However, a material having a crystal axis that is locally changed in direction thereof and a material containing local lattice defects are handled as a single crystal material. O represents oxygen. As described above, it is particularly preferred that R is Sc, A is Al, and M is Mg.

While the embodiment where the crystal of GaN as the Group III nitride is produced, the embodiment is not limited thereto. The Group III nitride in the embodiment may be a two-component, three-component, or four-component compound containing a Group III element (such as Al, Ga, or In) and nitrogen, and examples thereof include compounds represented by the general formula Al_{1-x-y}Ga_{y}InₓN (wherein x and y satisfy 0≦x≦1, 0≦y≦1, and 0≦1-x-y≦1). The group III nitride may contain a p-type or n-type impurity. For the protective layer 2, the low temperature buffer layer 3, the seed crystal layer 4, and the buffer layer 5 on the protective layer side described above, the materials thereof are GaN, but may also be the aforementioned compounds.

For example, a compound obtained by replacing at least a part of the Group III element (such as Al, Ga, or In) by boron (B), thallium (Tl), or the like may be used, and a compound obtained by replacing at least a part of nitrogen (N) by phosphorus (P), arsenic (As), antimony (Sb), bismuth (Bi), or the like may be used. Examples of the p-type impurity (acceptor) added to the Group III nitride include known p-type impurities, such as magnesium (Mg) and calcium (Ca). Examples of the n-type impurity (donor) added thereto include known n-type impurities, such as silicon (Si), sulfur (S), selenium (Se), tellurium (Te), oxygen (O), and germanium (Ge). The impurities (acceptor or donor) may be added as a combination of two or more elements. The crystals of the Group III nitride of this type can be produced in the similar manner as above.

According to the production method of the embodiment, a Group III nitride crystal with high quality can be obtained, and thereby for example, an LED device reduced in light emission unevenness and luminance reduction, and the like can be obtained.

What is claimed is:

1. A method for producing a Group III nitride crystal, comprising:
preparing an RAMO₄-containing substrate having an RAMO₄ substrate containing a single crystal represented by the general formula RAMO₄ (wherein R represents one or a plurality of a trivalent element selected from a group of elements including: Sc, In, Y, and a lanthanoid element, A represents one or a plurality of a trivalent element selected from a group of elements including: Fe(III), Ga, and Al, and M represents one or a plurality of a divalent element selected from a group of elements including: Mg, Mn, Fe(II), Co, Cu, Zn, and Cd), and a protective layer disposed on a region except for an epitaxial growth surface of the RAMO₄ substrate; and
forming a Group III nitride crystal on the epitaxial growth surface of the RAMO₄ substrate by a flux method.

2. The method for producing a Group III nitride crystal according to claim 1, wherein
the preparing the RAMO₄-containing substrate further comprises preparing a seed crystal layer containing a Group III nitride on the epitaxial growth surface of the RAMO₄ substrate, and
the forming the Group III nitride crystal comprises forming the Group III nitride crystal on the seed crystal layer.

3. The method for producing a Group III nitride crystal according to claim 2, wherein
the preparing the RAMO₄-containing substrate further comprises preparing a low temperature buffer layer containing a Group III nitride between the RAMO₄ substrate and the seed crystal layer.

4. The method for producing a Group III nitride crystal according to claim 1, wherein
the preparing the RAMO₄-containing substrate further comprises preparing, the protective layer to cover a side surface of the RAMO₄ substrate.

5. The method for producing a Group III nitride crystal according to claim 1, wherein
the preparing the RAMO₄-containing substrate further comprises preparing a buffer layer on the protective layer side between the protective layer and the RAMO₄ substrate, and
the buffer layer on the protective layer side has a thermal expansion coefficient that is between a thermal expansion coefficient of the protective layer and a thermal expansion coefficient of the RAMO₄ substrate.

6. The method for producing a Group III nitride crystal according to claim 1, wherein
in the general formula, R is Sc, A, is Al, and M is Mg.

7. An RAMO₄-containing substrate comprising:
an RAMO₄ substrate containing a single crystal represented by the general formula RAMO₄ (wherein R represents one or a plurality of a trivalent element selected from a group of elements including: Sc, In, Y, and a lanthanoid element, A represents one or a plurality of a trivalent element selected from a group of elements including: Fe(III), Ga, and Al, and M represents one or a plurality of a divalent element selected from a group of elements including: Mg, Mn, Fe(II), Co, Gu, Zn, and Gd), and
a protective layer disposed on a region except for an epitaxial growth surface of the RAMO₄ substrate.

8. The RAMO₄-containing substrate according to claim 7, wherein
the protective layer covers a side surface of the RAMO₄ substrate.

9. The RAMO₄-containing substrate according to claim 7, further comprising
a seed crystal layer containing a Group III nitride on the epitaxial growth surface of the RAMO₄ substrate.

10. The RAMO₄-containing substrate according to claim 9, further comprising
a low temperature buffer layer containing a Group III nitride between the epitaxial growth surface of the RAMO₄ substrate and the seed crystal layer.

11. The RAMO₄-containing substrate according to claim 7, wherein
the RAMO₄-containing substrate further comprises a buffer layer on the protective layer side between the RAMO₄ substrate and the protective layer, and
the buffer layer on the protective layer side has a thermal expansion coefficient that is between a thermal expansion coefficient of the protective layer and a thermal expansion coefficient of the RAMO₄ substrate.

12. The RAMO₄-containing substrate according to claim 7, wherein
in the general formula, R is Sc, A, is Al, and M is Mg.

13. The RAMO₄-containing substrate according to claim 7, wherein
the protective layer consists of a material that is not dissolved in a flux.

14. The RAMO₄-containing substrate according to claim 7, wherein
the protective layer consists of a material selected from a group of elements including: SiO₂, AlN, carbon, SiN, Al₂O₃, Ta, and GaN.

15. The RAMO₄-containing substrate according to claim 7, wherein
the protective layer consists of a material selected from a group of elements including: AlN, SiN, Al₂O₃, and GaN.
